(19) United States
(12) Patent Application Publication
(10) Pub. No.: US 2026/0335815 A1
(43) Pub. Date: Oct. 29, 2026

(54) SUBSTRATE PROCESSING CHAMBER AND SUBSTRATE PROCESSING DEVICE

(71) Applicant: SHINSUNG E&G CO., LTD., Gwacheon-si (KR)

(72) Inventors: Seong Cheon KIM, Yongin-si (KR); Sung Wook KO, Hwaseong-si (KR); Jun Young JEON, Incheon (KR); Dong Kwon KIM, Incheon (KR)

(21) Appl. No.: 19/135,371

(22) PCT Filed: Dec. 5, 2023
(86) PCT No.: PCT/KR2023/019854

§ 371 Date: Jun. 3, 2025

(30) Foreign Application Priority Data
Dec. 9, 2022 (KR) 10-2022-0171671
Nov. 30, 2023 (KR) 10-2023-0170950

(51) Int. Cl. B01D 53/26; B01D 46/00; B01D 53/06; H10P 72/00

(52) U.S. Cl. CPC B01D 53/261; B01D 46/0035; B01D 46/0036; B01D 53/06; H10P 72/0462; B01D 2257/80; B01D 2258/0216; B01D 2259/40098; B01D 2259/402

(57) ABSTRACT

Provided is a device for manufacturing a semiconductor or a display panel and, more specifically, to a substrate processing device and a substrate processing chamber having a dehumidifying unit integrated with a fan filter unit within the chamber. The substrate processing chamber comprises: a chamber body; and a dehumidifying unit provided inside the chamber body and adsorbing moisture in the air to produce dry air.

### TECHNICAL FIELD

The present invention relates to a device for manufacturing a semiconductor or display panel, more specifically to a substrate processing device and a substrate processing chamber having a dehumidifying unit provided integrally with a fan filter unit within the chamber.

### BACKGROUND ART

A semiconductor device or display panel is manufactured through continuous processes in fabrication equipment, and the manufacturing processes are divided into pre-processes and post-processes.

The pre-processes are processes of forming a circuit pattern on a substrate (for example, a wafer or circular glass) to complete a chip. The pre-processes include a deposition process of forming a thin layer on the substrate, a photo lithography process of transferring a photo resist on the thin layer using a photo mask, an etching process of selectively removing portions not necessary with a chemical or reactive gas to form a desired circuit pattern on the substrate, an ashing process of removing residual photoresist after etching, an ion implantation process of implanting ions into a portion connected to a circuit pattern to allow the portion to have characteristics of an electronic device, and a cleaning process of removing contamination sources from the substrate.

The post-processes are processes of performing post-machining the completed product obtained through the pre-processes or evaluating the performance of the product. The post-processes include a substrate test process of testing the operations of the chips on substrates to sort good products and bad products, a package process of cutting and separating the chips through dicing, die bonding, wire bonding, molding, and marking to provide the shapes of the products, and a final test process of finally testing the characteristics and reliability of the products through electrical characteristic tests, burn-in tests, etc.

For example, a cluster system as a piece of equipment for fabricating a semiconductor device consists of an index module, a load-lock chamber, a transfer chamber, and a process chamber.

The index chamber has load ports located on one side thereof and a transfer robot disposed therein. The load ports serve to seat containers in which a plurality of substrates are received, such as Front Opening Unified Pods (FOUPs), thereonto.

The index chamber performs the exchange of the substrates through the load ports with the substrates in the transfer chamber. The transfer chamber has a transfer robot adapted to load or unload the substrates to and from the process chamber.

The process chamber serves to make use of a plasma to perform given processes (etching, deposition, etc.) for the substrates.

Recently, a semiconductor fabrication process decreases in design rules and increases in a degree of integration, and therefore, levels of requirements for environmental management of particle contamination on wafers become high.

To suppress particle contamination from occurring in the fabrication equipment in conventional fabrication processes, air having a temperature of 23 °C and humidity of 40 to 45% in the environment of the fabrication equipment (FAB) is supplied to the interior of the index chamber such as an Equipment Front End Module (EFEM) at a flow rate of 0.3 to 0.5 m/sec through a Fan Filter Unit (FFU) and an Ultra Low Particulate Air (ULPA) filter, while keeping positive pressure airflows.

Further, a piece of equipment for specific processes is provided with an air filter adapted to filter harmful materials in fabrication processes, such as ammonia, hydrofluoric acid, ozone, and the like.

In this case, however, humidity increases to easily react with the residual gas on a wafer after the processing has been completed, thereby creating particles. According to the existing environment conditions of the index chamber, the internal air of the FAB is supplied through the fan filter unit, without any control of the humidity in the chamber, so that the humidity existing in the air is likely to react with the residual gas on the wafer to cause particles or defects to be created with ease.

To solve such problems, studies have been made, and for example, one example of them is disclosed in Korean Patent Application Laid-open No. 10-2021-0079632. Referring in detail to FIG. 1, an EFEM has an FFU 141 and an ULPA filter 142 located therein and a dry air supply device 100 located on the outside thereof to supply dry air thereto.

In detail, the dry air produced from the dry air supply device 100 is supplied to the interior of the chamber and passes through the FFU 141 and the ULPA filter 142, so that clean dry air is continuously supplied to the chamber.

In a semiconductor etching process, a metal film-forming process, a clean process, and a process of using a chemical gas or liquid chemical, air whose humidity (less than or equal to 20%) substantially decreases is supplied to a buffer space for processing the wafer, such as the EFEM, so that the air does not react with the residual gas and harmful chemical components, thereby preventing particles and defects on the wafer from being created and improving a yield.

As the dry air is consistently supplied, unintended reactions are advantageously suppressed, but the dry air supply device 100 has to be separately located on the outside of the EFEM chamber. Besides, a dry air supply pipe for supplying the dry air is additionally connected between the dry air supply device 100 and the chamber.

As a result, the fabrication equipment becomes bulky in volume, thereby undesirably increasing a space (area) for installing it.
(Patent document 1) Korean Patent Application Laid-open No. 10-2021-0079632
(Patent document 2) Korean Patent No. 10-1044315
(Patent document 3) Korean Patent No. 10-2329696

### DISCLOSURE

### Technical Problem

Accordingly, the present invention has been made in view of the above-mentioned problems occurring in the related art, and it is an object of the present invention to provide a substrate processing chamber that is provided with a dehumidifying unit and a filter unit therein to supply clean dry air thereinto.

It is another object of the present invention to provide a substrate processing chamber that is capable of re-circulating dry air, thereby achieving the reduction of energy consumption.

It is yet another object of the present invention to provide a substrate processing device that is capable of allowing a fan unit, a filter unit, and a dehumidifying unit to be selectively located in chambers required for fabrication processes, such as an index chamber, a process chamber, a transfer chamber, and the like.

### Technical Solution

To accomplish the above-mentioned objects, according to one aspect of the present invention, there is provided a substrate processing chamber including: a chamber body; and a dehumidifying unit provided inside the chamber body and adapted to adsorb moisture in the air to produce dry air.

Further, the substrate processing chamber may include a fan unit located inside the chamber body to produce airflows in the chamber body.

Furthermore, the substrate processing chamber may include a filter unit located inside the chamber body to filter particles in the air.

Besides, the dehumidifying unit may adsorb the moisture in the air supplied from the fan unit, and the filter unit may filter the dry air produced by the dehumidifying unit and remove the particles in the air.

Further, the filter unit may filter the air supplied from the fan unit and remove the particles in the air, and the dehumidifying unit may adsorb the moisture in the clean air filtered by the filter unit.

Besides, the dehumidifying unit may include: rotors adapted to adsorb the moisture in the air in the chamber body, while rotating; a heater adapted to remove the moisture adsorbed onto the rotors; and an exhauster adapted to exhaust the moisture removed by means of the heater to the outside of the chamber body.

Moreover, the rotors may consist of a first rotor and a second rotor having the shapes of circular plates, and the first rotor and the second rotor may be spaced apart from each other on the same planar surface, without any overlap between the circumferences thereof.

Further, the heater may be located on tops or undersides of the first rotor and the second rotor to simultaneously or individually heat heating zones of the first rotor and the second rotor, and the heating zones may have the shapes of circular sectors.

Besides, the heater may have the shape of a rectangle and a pair of diagonal vertexes located on the vertical line passing through the centers of the first rotor and the second rotor.

Moreover, the first rotor and the second rotor may rotate simultaneously or individually.

Further, the first rotor and the second rotor may include process zones adapted to adsorb moisture in the air supplied from the fan unit, regeneration zones located on top of the heater to remove the moisture, and cooling zones located between the process zones and the regeneration zones to cool the air raised in temperature by the heater.

In this case, the heater may be located on the undersides of the regeneration zones.

Further, the substrate processing chamber may include a bypass pipe provided to circulatedly supply the internal air of the chamber body to the dehumidifying unit.

Furthermore, the substrate processing chamber may include a chemical filter located on top of the fan unit to remove acid and base gases, an airflow diffusion plate located under the dehumidifying unit to diffuse the airflows, and an oil-wetted filter adapted to remove the moisture before the moisture removed by the heater is exhausted to the outside of the chamber body.

Besides, the substrate processing chamber may include load ports located on one side of the chamber body to seat containers in which substrates are received thereonto.

In addition, the substrate processing chamber may include a transfer robot located in the chamber body to transfer the substrates.

Further, the substrate processing chamber may include any one of an etching unit and a deposition unit located in the chamber body to perform processes for the substrates.

To accomplish the above-mentioned objects, according to another aspect of the present invention, there is provided a substrate processing device including: an index chamber having load ports adapted to seat containers in which substrates are received thereonto; a process chamber for performing given processes for the substrates; and a transfer chamber having a transfer robot provided therein to transfer the substrates between the index chamber and the process chamber, wherein one or more chambers of the index chamber, the process chamber, and the transfer chamber have dehumidifying units adapted to adsorb moisture in the air thereonto.

Further, one or more chambers of the index chamber, the process chamber, and the transfer chamber may have fan units adapted to produce airflows therein.

Furthermore, one or more chambers of the index chamber, the process chamber, and the transfer chamber may have filter units adapted to filter particles in the air therein.

Moreover, each dehumidifying unit may include: rotors adapted to adsorb the moisture in the air in a chamber body of the corresponding chamber, while rotating; a heater adapted to remove the moisture adsorbed onto the rotors; and an exhauster adapted to exhaust the moisture removed by means of the heater to the outside of the chamber body.

Besides, the rotors may consist of a first rotor and a second rotor having the shapes of circular plates, and the first rotor and the second rotor may be spaced apart from each other on the same planar surface, without any overlap between the circumferences thereof.

Further, the heater may be located on tops or undersides of the first rotor and the second rotor to simultaneously or individually heat heating zones of the first rotor and the second rotor, and the heating zones may have the shapes of circular sectors.

Moreover, one or more chambers of the index chamber, the process chamber, and the transfer chamber may have bypass pipes adapted to circulatedly supply the internal air of the corresponding chamber bodies to the corresponding dehumidifying units.

### Advantageous Effects of Invention

According to the present invention, the substrate processing chamber is provided with the fan unit, the filter unit, and the dehumidifying unit therein, thereby effectively removing the moisture and particles from the internal air thereof.

As a result, the clean dry air is supplied to the chamber to prevent unintended reactions on the surface of the substrate from happening and avoid the particles from being attached to the surface of the substrate.

The existing dehumidifying unit is separately located to the outside of the chamber, while the fan unit and the filter unit are located in the interior of the chamber, but according to the present invention, the dehumidifying unit is provided integrally with the fan unit and the filter unit within the chamber, thereby reducing the volume and installation space of fabrication equipment and decreasing a fabrication cost.

Further, the rotors and the heater of the dehumidifying unit are optimizedly arranged, thereby improving dehumidifying efficiencies and reducing the volume of the fabrication equipment.

Additionally, the dry air exhausted through the dehumidifying unit is circulated and re-supplied to the dehumidifying unit, thereby achieving the reduction of energy consumption.

Lastly, the fan unit, the filter unit, and the dehumidifying unit, which are provided integrally with one another within the chamber, are applicable to all chambers, such as, the index chamber, the process chamber, and the transfer chamber, in manufacturing processes for semiconductors, display panels, or other products.

### BRIEF DESCRIPTION OF DRAWINGS

FIG. 1 is a diagram showing a conventional index module (EFEM) with a dry air supply device located separately therefrom.

FIG. 2 is a perspective view showing a substrate processing device according to an embodiment of the present invention.

FIG. 3 is a sectional view showing the substrate processing device of FIG. 2.

FIG. 4 is a sectional view showing main units of FIG. 3.

FIG. 5 is a sectional view showing a dehumidifying unit of FIG. 4.

FIG. 6 is a sectional view showing another example of a heater provided in the dehumidifying unit according to the present invention.

FIG. 7 is a perspective view showing a substrate processing device according to another embodiment of the present invention.

FIGS. 8 to 10 are perspective views showing various examples in which the dehumidifying unit is mounted on the chamber according to the present invention.

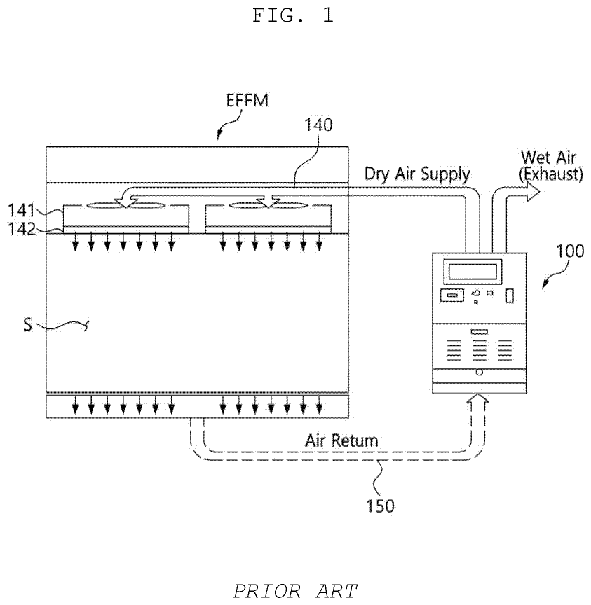

### BEST MODE FOR INVENTION

Hereinafter, embodiments of the present invention will be described in detail with reference to the accompanying drawings.

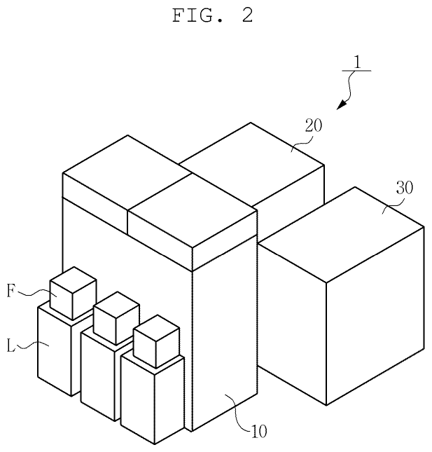

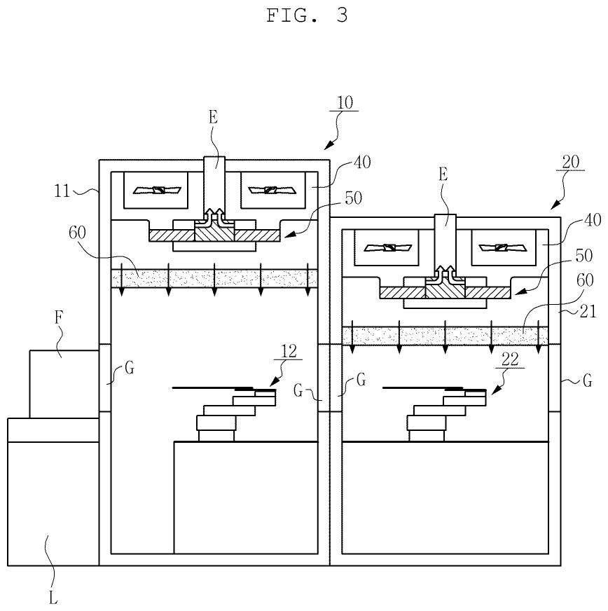

Referring to FIGS. 2 to 3, a substrate processing device 1 according to an embodiment of the present invention includes an index chamber 10, a transfer chamber 20, and a process chamber 30.

The index chamber 10 has load ports L located on one side of a chamber body 11 to seat containers F thereonto and a transfer robot 12 provided therein to transfer a substrate. To transfer the substrate, the chamber body 11 has gates G located on the side walls thereof.

Each container F is any one of a Front Open Unified Pod (FOUP), Front Opening Shipping Box (FOSB), Multiple Application Carrier (MACs), and Pod.

According to the embodiment of the present invention, further, the index chamber 10 may be an equipment front end module (EFEM).

The load ports L are adapted to load and unload substrates to be processed onto and from the index chamber 10, and the containers F in which the substrates are received are seated onto the load ports L.

The load ports L serve to open the containers F and transfer the substrates received in the containers F to the index chamber 10, and in this case, one of the load ports L serves to load the substrates not processed yet to the process chamber 30, and another load port L serves to unload the substrates to which given processes are performed from the process chamber 30.

When the substrates not processed yet are transferred to the index chamber 10 or the processed substrates are transferred to the outside, the containers F serve to make the transfer of the substrates convenient and block contact of air with the substrates.

Next, the process chamber 30 is a chamber in which the given processes for the substrates located inside a chamber body thereof are performed. The process chamber 30 has a table (not shown) on which the substrate is seated, and the chamber body has a gate (not shown) on the side wall thereof to transfer the substrates.

For example, the given processes may include a deposition process of forming a thin layer on the substrate, a photo lithography process of transferring a photo resist on the thin layer using a photo mask, an etching process of selectively removing portions not necessary with a chemical or reactive gas to form a desired circuit pattern on the substrate, an ashing process of removing residual photoresist after etching, an ion implantation process of implanting ions into a portion connected to a circuit pattern to allow the portion to have characteristics of an electronic device, and a cleaning process of removing contamination sources from the substrate.

The process chamber 30 performs the given processes using a plasma or in vacuum or atmospheric conditions.

Next, the transfer chamber 20 has a transfer robot 22 located inside a chamber body 21 to transfer the substrates between the index chamber 10 and the process chamber 30. To transfer the substrates, the chamber body 21 has gates G on the side walls thereof.

To do this, the transfer chamber 20 has the transfer robot 22 located inside the chamber body 21, and the transfer robot 22 transfers the substrate not processed yet to the process chamber or the substrate processed in the process chamber 30 to the index chamber 10.

As mentioned above, the substrate processing device 1 according to the present invention includes the index chamber 10 and the transfer chamber 20, and in this case, the index chamber 10 and the transfer chamber 20 have respective fan units 40, dehumidifying units 50, and filter units 60 located therein in such a way as to be integrated with one another. If necessary, further, the process chamber 30 may have a fan unit 40, a dehumidifying unit 50, and a filter unit 60 located therein in such a way as to be integrated with one another.

As shown in FIG. 3, the index chamber 10 and the transfer chamber 20 have the fan units 40, dehumidifying units 50, and filter units 60 located in their respective chamber bodies 11 and 21. In more detail, the fan unit 40, the dehumidifying unit 50, and the filter unit 60 are located in upward and downward directions on top of the interior of the chamber body 11 of the index chamber 10.

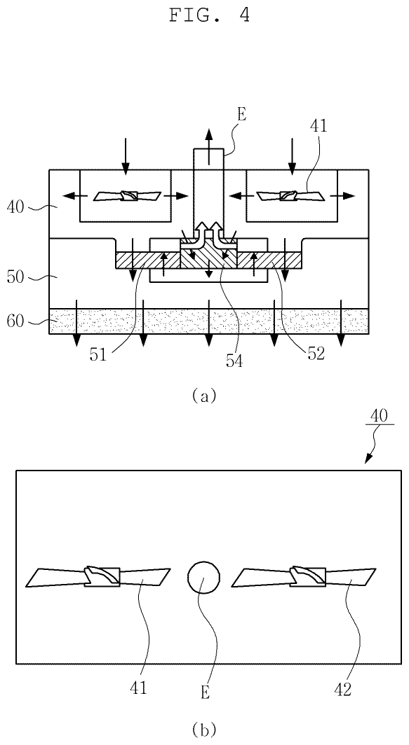

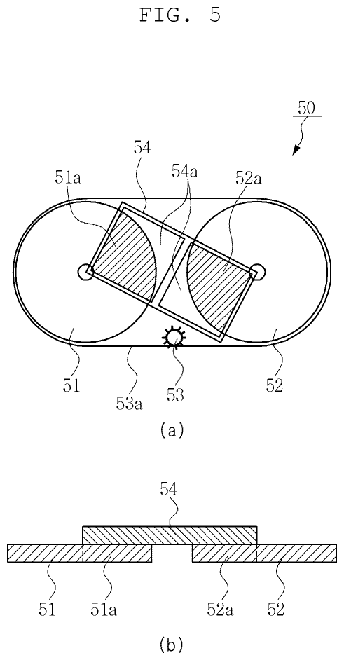

Referring to FIGS. 4 and 5, the respective fan units 40, dehumidifying units 50, and filter units 60 located in the respective chamber bodies 11 and 21 will be explain in detail.

Each fan unit 40 has a pair of fans 41 and 42 located side-by-side in a horizontal direction to produce air flows in the corresponding chamber body 11 or 21, circulate the internal air of the chamber body, and supply the air to the dehumidifying unit 50.

The dehumidifying unit 50 has a pair of rotors 51 and 52 located side-by-side in a horizontal direction in such a way as to be spaced apart from each other, when viewed on top thereof, without any overlap between the circumferences thereof (See FIG. 5a). That is, a distance between the first rotor 51 and the second rotor 52 is greater than the sum of radii of the first rotor 51 and the second rotor 52.

The first rotor 51 and the second rotor 52 rotate to adsorb the moisture contained in the air and produce dry air. According to the embodiment of the present invention, a geared motor 53 is located in the dehumidifying unit 50 to provide a decelerated driving force so that the first rotor 51 and the second rotor 52 interlock with each other and rotate at the same speed. In detail, the driving force of the geared motor 53 is transferred to the first rotor 51 and the second rotor 52 through power transfer means such as a timing belt 53a or idle gear and thus enables them to rotate.

Further, the dehumidifying unit 50 has a heater 54 adapted to remove the moisture adsorbed onto the first rotor 51 and the second rotor 52 so that the first rotor 51 and the second rotor 52 continuously adsorb the moisture in the air. In detail, the heater 54 re-dries the first rotor 51 and the second rotor 52 into which the moisture is adsorbed and keeps the conditions of the first rotor 51 and the second rotor 52 in which the moisture in the air can be adsorbed.

According to the embodiment of the present invention, the heater 54 is configured to supply heat to tops and undersides of the first rotor 51 and the second rotor 52.

According to the embodiment of the present invention, further, the heater 54 has the shape of a rectangle and is located on tops of the first rotor 51 and the second rotor 52.

Further, the heater 54 has a pair of heating plates 54a on the underside thereof, and heating zones 51a and 52a of the first rotor 51 and the second rotor 52, which are heated by the heating plates 54a, have the shapes of circular sectors. In detail, the first rotor 51 and the second rotor 52 rotate and thus adsorb the moisture in the air, and further, the heating zones 51a and 52a having the shapes of the circular sectors are heated to separate the moisture from the first rotor 51 and the second rotor 52.

Like this, exhausters E are provided to exhaust the moisture separated from the first rotors 51 and the second rotors 52 through the heaters 54 to the outsides of the chamber bodies 11 and 21. In detail, the first rotors 51 and the second rotors 52 are dried by the heaters 54, and simultaneously, air containing a large amount of moisture is produced. In this case, the air containing a large amount of moisture is exhausted to the outsides of the chamber bodies 11 and 21 through the exhausters E.

The air containing a large amount of moisture, which passes through the dehumidifying unit 50, turns into dry air containing a small amount of moisture, and the dry air passes through the filter unit 60 and is produced as clean dry air.

The filter unit 60 is desirably an Ultra Low Particulate Air (ULPA) filter, and through the ULPA filter, the filter unit 60 keeps positive pressure airflows, while supplying the air at a flow rate of 0.3 to 0.5 m/sec to the corresponding chamber.

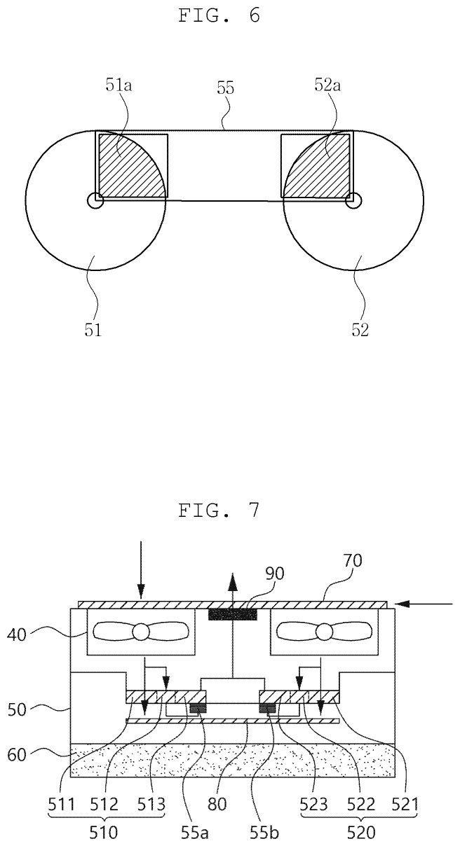

FIG. 6 shows another example of the heater 54 of the dehumidifying unit 50 according to the present invention.

As shown, a heater 55 has the shape of a rectangle, while having a pair of heating plates, which is the same as in the embodiment as shown in FIG. 5. Further, heating zones 51a and 52a having the shapes of circular sectors are formed, which is the same as in the embodiment as shown in FIG. 5.

According to the embodiment as shown in FIG. 5, a pair of diagonal vertexes of the rectangular heater 54 are located on the vertical line passing through the centers of the first rotor 51 and the second rotor 52, but according to the embodiment as shown in FIG. 6, a pair of long side vertexes of the rectangular heater 55 are located on the vertical line passing through the centers of the first rotor 51 and the second rotor 52.

Unlike the embodiments as shown in FIGS. 5 and 6, a heater may be separated into a first heater and a second heater corresponding to the first rotor and the second rotor. Further, the heater may have the shape of a circle or polygon, not a rectangle.

Furthermore, the first rotor and the second rotor rotate in the same direction as each other by means of the geared motor, but they may rotate in the opposite direction to each other. For example, the first rotor rotates in a clockwise direction, whereas the second rotor rotates in a counterclockwise direction.

Moreover, the driving source for driving the first rotor and the second rotor may be separately divided into a first geared motor and a second geared motor. In this case, the rotational speeds of the first rotor and the second rotor may be differently controlled.

Unlike the above-mentioned embodiment of the present invention, further, the filter unit may be located under the fan unit, and the dehumidifying unit may be located integrally with the underside of the filter unit.

Besides, a bypass pipe is desirably provided to circulatedly supply the internal air of the chamber body to the dehumidifying unit. The bypass pipe allows energy consumption to be reduced.

Hereinafter, operations of the substrate processing device 1 according to the embodiment of the present invention will be explained in detail.

First, the fans 41 and 42 of the fan unit 40 of the index chamber 10 or the transfer chamber 20 supply outside air or the internal air of the chamber body 11 or 21 to the dehumidifying unit 50. In this case, the air is introduced above the fans 41 and 42 and exhausted to both sides of the fans 41 and 42 (See arrows of FIG. 4).

Next, the air exhausted to both sides of the fans 41 and 42 is supplied to tops of the first rotor 51 and the second rotor 52 so that the moisture contained in the air is adsorbed onto the first rotor 51 and the second rotor 52 that are rotating, thereby producing dry air.

After that, the dry air passes through the filter unit 60, is filtered through the particle filter, and is supplied downward as clean air.

While the first rotor 51 and the second rotor 52 are rotating, further, the heater 54 or 55 applies heat to the heating zones 51a and 52a and dries the first rotor 51 and the second rotor 52. The air containing a large amount of moisture produced during the process is exhausted to the outside of the chamber body 11 or 21 through the exhauster E.

Through the above-mentioned processes, clean dry air is supplied to the interior of the chamber body and kept thereinto.

### Mode for Invention

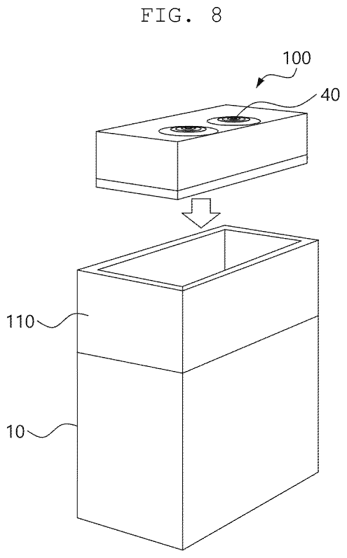

FIG. 7 shows a substrate processing device according to another embodiment of the present invention.

Explanations of the same components as in FIG. 4 will be avoided.

As shown in FIG. 7, a chemical filter 70 is located on top of a fan unit 40. The chemical filter 70 removes acid and base gases such as ammonia, sulfur oxides, chlorine compounds, and the like.

Further, a first rotor 510 and a second rotor 520, which have circular shapes, have respective process zones 511 and 521, regeneration zones 513 and 523, and cooling zones 512 and 522.

The process zones 511 and 521 serve to adsorb moisture in the air supplied from the fan unit 40 and thus supply dry air, the regeneration zones 513 and 523 serve to remove the moisture by means of a pair of heaters 55a and 55b, and the cooling zones 512 and 522 are located between the process zones 511 and 521 and the regeneration zones 513 and 523 to cool the air raised in temperature by the pair of heaters 55a and 55b.

Unlike the embodiment as shown in FIG. 4, the substrate processing device according to another embodiment of the present invention includes the pair of heaters 55a and 55b. That is, the heaters 55a and 55b are located on the undersides of the first regeneration zone 513 and the second regeneration zone 523 to remove the moisture from the first regeneration zone 513 and the second regeneration zone 523.

The air passing through the regeneration zones 513 and 523 is exhausted to the outside of the chamber through an exhauster. Before the air is exhausted, in this case, the air passes through an oil-wetted filter 90 so that it is exhausted after moisture has been removed therefrom.

Further, the dry air, which passes through the process zones 511 and 521, passes through an airflow diffusion plate 80 and is uniformly sprayed.

The airflow diffusion plate 80 has the shape of a perforated plate with a plurality of holes.

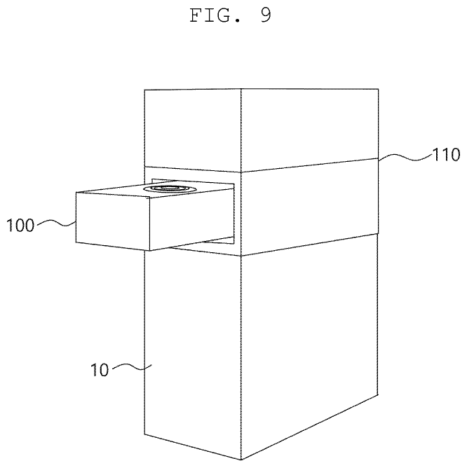

FIGS. 8 to 10 show various examples in which a dehumidifying module 100 is mounted on the chamber according to the present invention.

For example, FIG. 8 shows an example in which the dehumidifying module 100 is mounted onto a hollow mounting portion 110 formed on top of the index chamber 10.

The dehumidifying module 100 is configured to combine the chemical filter 70, the fan unit 40, the dehumidifying unit 50, and the filter unit 60 with one another.

According to the embodiment of the present invention, the dehumidifying module 100 is located on the uppermost portion of the corresponding chamber, and in this case, the substrate processing device becomes small in volume, thereby being advantageously disposed on a minimal space.

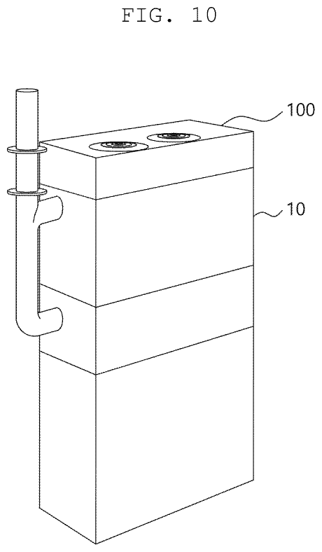

FIG. 9 shows an example in which the dehumidifying module 100 is inserted into the side surface of the corresponding chamber, and FIG. 10 shows an example in which the dehumidifying module 100 is located on top of the corresponding chamber.

As mentioned above, the preferred embodiment of the present invention has been disclosed in the specification and drawings. However, this does not limit the invention within specific embodiments and it should be understood that the invention covers all the modifications, equivalents, and replacements within the idea and technical scope of the invention. Further, the objects or effectiveness suggested in the invention are included or have to be included in the specific embodiment of the invention, and therefore, it is to be understood that the scope of the present invention is not limited thereby. Therefore, persons skilled in the relevant art can appreciate that many modifications and variations are possible in light of the above teachings. It is therefore intended that the scope of the invention be limited not by this detailed description, but rather by the claims appended hereto.

### INDUSTRIAL APPLICABILITY OF INVENTION

The present invention relates to the substrate processing device that is provided with the dehumidifying unit and the filter unit in the chamber where the given processes for the substrate are performed, so that clean dry air is supplied to the chamber.

1. A substrate processing chamber comprising:
a chamber body; and
a dehumidifying unit provided inside the chamber body and adapted to adsorb moisture in the air to produce dry air.

2. The substrate processing chamber according to claim 1, further comprising:
a fan unit located inside the chamber body to produce airflows in the chamber body; or
a filter unit located inside the chamber body to filter particles in the air.

3. The substrate processing chamber according to claim 2, wherein the dehumidifying unit comprises:
rotors adapted to adsorb the moisture in the air in the chamber body, while rotating;
a heater adapted to remove the moisture adsorbed onto the rotors; and
an exhauster adapted to exhaust the moisture removed by means of the heater to the outside of the chamber body.

4. The substrate processing chamber according to claim 3, wherein the rotors consist of a first rotor and a second rotor having the shapes of circular plates, and the first rotor and the second rotor are spaced apart from each other on the same planar surface, without any overlap between the circumferences thereof.

5. The substrate processing chamber according to claim 4, wherein the heater is located on tops or undersides of the first rotor and the second rotor to simultaneously or individually heat heating zones of the first rotor and the second rotor, and the heating zones have the shapes of circular sectors.

6. The substrate processing chamber according to claim 4, wherein the first rotor and the second rotor comprise
process zones adapted to adsorb moisture in the air supplied from the fan unit,
regeneration zones located on top of the heater to remove the moisture, and
cooling zones located between the process zones and the regeneration zones to cool the air raised in temperature by the heater.

7. The substrate processing chamber according to claim 2, further comprising a chemical filter located on top of the fan unit to remove acid and base gases.

8. The substrate processing chamber according to claim 1, further comprising an airflow diffusion plate located under the dehumidifying unit to diffuse the airflows.

9. The substrate processing chamber according to claim 3, further comprising an oil-wetted filter adapted to remove the moisture before the moisture removed by the heater is exhausted to the outside of the chamber body.

10. A substrate processing device comprising:
an index chamber having load ports adapted to seat containers in which substrates are received thereonto;
a process chamber for performing given processes for the substrates; and
a transfer chamber having a transfer robot provided therein to transfer the substrates between the index chamber and the process chamber,
wherein one or more chambers of the index chamber, the process chamber, and the transfer chamber have dehumidifying units adapted to adsorb moisture in the air thereonto.

11. The substrate processing device according to claim 10, wherein one or more chambers of the index chamber, the process chamber, and the transfer chamber have fan units adapted to produce airflows therein and filter units adapted to filter particles in the air therein.

12. The substrate processing device according to claim 10, wherein each dehumidifying unit comprises:
rotors adapted to adsorb the moisture in the air in a chamber body of the corresponding chamber, while rotating;
a heater adapted to remove the moisture adsorbed onto the rotors; and
an exhauster adapted to exhaust the moisture removed by means of the heater to the outside of the chamber body.

13. The substrate processing device according to claim 12, wherein the rotors consist of a first rotor and a second rotor having the shapes of circular plates, and the first rotor and the second rotor are spaced apart from each other on the same planar surface, without any overlap between the circumferences thereof.

14. The substrate processing device according to claim 13, wherein the first rotor and the second rotor comprise
process zones adapted to adsorb moisture in the air supplied from the fan unit,
regeneration zones located on top of the heater to remove the moisture, and
cooling zones located between the process zones and the regeneration zones to cool the air raised in temperature by the heater, and
the heater is located on the undersides of the regeneration zones.
